(19) United States
(12) Patent Application Publication
(10) Pub. No.: US 2020/0177195 A1
(43) Pub. Date: Jun. 4, 2020

(54) ANALOG-TO-DIGITAL CONVERTER AND OPERATING METHOD OF ANALOG-TO-DIGITAL CONVERTER

(71) Applicant: ELECTRONICS AND TELECOMMUNICATIONS RESEARCH INSTITUTE, Daejeon (KR)

(72) Inventors: Young-deuk JEON, Sejong-si (KR); MIN-HYUNG CHO, Daejeon (KR); JOO HYUN LEE, Daejeon (KR)

(21) Appl. No.: 16/701,482

(22) Filed: Dec. 3, 2019

(30) Foreign Application Priority Data
Dec. 4, 2018 (KR) 10-2018-0154818
Nov. 18, 2019 (KR) 10-2019-0147372

(51) Int. Cl. H03M 1/06; G06N 3/063

(52) U.S. Cl. CPC H03M 1/06; G11C 8/08; G06N 3/063

(57) ABSTRACT

An analog-to-digital converter includes a capacitor array including capacitors, an amplifier receiving an input current through an input node and integrating the input current, using the capacitor array, in a first mode, a switch array including switches respectively connected to the capacitors, successive approximation logic performing a successive approximation by selectively connecting each of the capacitors to one of a common voltage and a reference voltage through the switches, in a second mode, a comparator comparing the common voltage with an output of the amplifier and output a pulse signal based on the comparison result, a counter counting the pulse signal in the first mode, a register sequentially storing values of the pulse signal, in the second mode, and error correction logic storing an output of the counter as upper bits and an output of the register as lower bits and performing error correction.

### CROSS-REFERENCE TO RELATED APPLICATIONS

This U.S. non-provisional patent application claims priority under 35 U.S.C. § 119 of Korean Patent Application No. 10-2018-0154818, filed on Dec. 4, 2018, and 10-2019-0147372, filed on Nov. 18, 2019, the entire contents of which are hereby incorporated by reference.

### BACKGROUND

### 1. Field of the Invention

Embodiments of the inventive concept relate to an analog-to-digital converter, and more particularly, relate to an analog-to-digital converter that performs a conversion using two or more algorithms sharing at least one component.

### 2. Description of Related Art

The analog-to-digital converter is configured to convert an analog signal into digital bits. The analog-to-digital converter may be designed based on various algorithms. For example, depending on an environment in which the analog-to-digital converter is used, the analog-to-digital converter may be designed based on one of the various algorithms.

To increase a resolution of the analog-to-digital converter, the size of the analog-to-digital converter may be increased and a conversion time of the analog-to-digital converter may be increased. These problems are hampering the adoption of analog-to-digital converters in applications that require high resolution.

### SUMMARY

Embodiments of the inventive concept provide an analog-to-digital converter and a method of operating the analog-to-digital converter with improved resolution while preventing an increase in size or an increase in conversion time.

According to an exemplary embodiment, an analog-to-digital converter includes a capacitor array including a plurality of capacitors, an amplifier to receive an input current through an input node and integrate the input current, using the capacitor array, in a first mode, a switch array including a plurality of switches respectively connected to the plurality of capacitors, successive approximation logic to perform a successive approximation by selectively connecting each of the plurality of capacitors to one of a common voltage and a reference voltage through the plurality of switches, in a second mode, a comparator to compare the common voltage with an output of the amplifier and output a pulse signal based on the comparison result, a counter configured to count the pulse signal in the first mode, a register to sequentially store values of the pulse signal, in the second mode, and error correction logic to store an output of the counter as upper bits and an output of the register as lower bits and perform error correction to generate digital bits.

In an embodiment, the analog-to-digital converter further includes a first switch and a resistor connected in series between a first input of the amplifier and a ground node, a second switch connected between the first input of the amplifier and the input node, a third switch connected between the output of the amplifier and the first input of the amplifier, a fourth switch connected between a first terminal of the capacitor array and the first input of the amplifier, a fifth switch connected between a second terminal of the capacitor array and the output of the amplifier, and a sixth switch connected between the first terminal of the capacitor array and the switch array.

In an embodiment, the first input of the amplifier is a negative input, and the common voltage is input to a second input of the amplifier.

In an embodiment, the analog-to-digital converter further includes control logic to receive a first clock signal, control the first to sixth switches in the first mode and the second mode in response to the first clock signal, generate a second clock signal from the first clock signal, and supply the second clock signal to the switch array, the successive approximation logic, and the register in the second mode.

In an embodiment, in a reset interval of the first mode, the first switch, the third switch, the fourth switch, and the fifth switch are turned on, and the second switch and the sixth switch are turned off.

In an embodiment, in an initialization interval of the first mode, the first switch, the fourth switch, and the fifth switch are turned on, and the second switch, the third switch, and the sixth switch are turned off.

In an embodiment, in a sampling interval of the first mode, when an output of the comparator is a low level, the second switch, the fourth switch and the fifth switch are turned on, and the first switch, the third switch and the sixth switch are turned off.

In an embodiment, in a sampling interval of the first mode, when an output of the comparator is a high level, the first switch, the second switch, the fourth switch, and the fifth switch are turned on, and the third switch, and the sixth switch are turned off.

In an embodiment, in a hold and comparison interval of the first mode, the fourth switch, and the fifth switch are turned on, and the first switch, the second switch, the third switch, and the sixth switch are turned off.

In an embodiment, in the second mode, the fifth switch and the sixth switch are turned on, and the first switch, the second switch, the third switch, and the fourth switch are turned off.

In an embodiment, the sixth switch includes a plurality of first sub-switches respectively connected between the plurality of capacitors of the capacitor array and the plurality of switches, the fourth switch includes a plurality of second sub-switches connected between the plurality of capacitors and a common node, and the common node is commonly connected to the first switch, the second switch, and the third switch.

In an embodiment, in a reset interval of the first mode, the output of the amplifier is reset to the common voltage.

In an embodiment, in an initialization interval of the first mode, the output of the amplifier is initialized to a second reference voltage greater than the common voltage.

In an embodiment, in a sampling interval of the first mode, when the output of the amplifier is greater than the common voltage, a voltage level of the output of the amplifier decreases, and when the output of the amplifier is less than the common voltage, the voltage level of the output of the amplifier increases.

In an embodiment, in a hold and comparison interval of the first mode, the comparator outputs the pulse signal when a voltage level of the output of the amplifier is less than the common voltage.

In an embodiment, when entering the second mode from the first mode, when a voltage level of the output of the amplifier is greater than the common voltage, the voltage level is maintained, and when the voltage level is less than the common voltage, the voltage level is increased.

In an embodiment, in the second mode, the successive approximation logic performs the successive approximation with respect to a voltage level of the output of the amplifier between a second reference voltage and the common voltage.

In an embodiment, the input current is transferred from a plurality of synapse elements of a neuromorphic processor.

According to an exemplary embodiment, a method of operating an analog-to-digital converter includes receiving an input current, generating at least two first bits by integrating the input current, and generating a result of the integration, generating at least two second bits by performing a successive approximation on the result of the integrating, and outputting the at least two first bits as upper bits and the at least two second bits as lower bits.

In an embodiment, in generating the first bits and generating the second bits, capacitors and a comparator are shared and used.

### BRIEF DESCRIPTION OF THE FIGURES

The above and other objects and features of the inventive concept will become apparent by describing in detail exemplary embodiments thereof with reference to the accompanying drawings.

FIG. 1 is a block diagram illustrating an analog-to-digital converter according to an embodiment of the inventive concept.

FIG. 2 is a diagram illustrating in more detail an analog-to-digital converter according to an embodiment of the inventive concept.

FIG. 3 is a diagram illustrating an example in which an analog-to-digital converter according to the embodiment of the inventive concept performs the conversion.

FIG. 4 is a diagram illustrating an example in which an analog-to-digital converter operates in a reset interval of a first mode.

FIG. 5 is a diagram illustrating an example in which an analog-to-digital converter operates in an initialization interval of a first mode.

FIG. 6 is a diagram illustrating an example in which an analog-to-digital converter operates in a sampling interval of a first mode.

FIG. 7 is a diagram illustrating an example in which an analog-to-digital converter operates in a hold and comparison interval of a first mode.

FIG. 8 is a diagram illustrating an example in which an analog-to-digital converter operates in a sampling interval of a second mode.

FIG. 9 is a diagram illustrating an example in which an analog-to-digital converter operates in a signal conversion interval of a second mode.

FIG. 10 is a diagram illustrating an example of a capacitor array and switches associated with it according to an embodiment of the inventive concept.

FIG. 11 is a flowchart describing a method of operating an analog-to-digital converter according to an embodiment of the inventive concept.

FIG. 12 is a block diagram illustrating a neuromorphic processor according to an embodiment of the inventive concept.

### DETAILED DESCRIPTION

Embodiments of the inventive concept will be described below in more detail with reference to the accompanying drawings. In the following descriptions, details such as detailed configurations and structures are provided merely to assist in an overall understanding of embodiments of the inventive concept. Modifications of the embodiments described herein can be made by those skilled in the art without departing from the spirit and scope of the inventive concept.

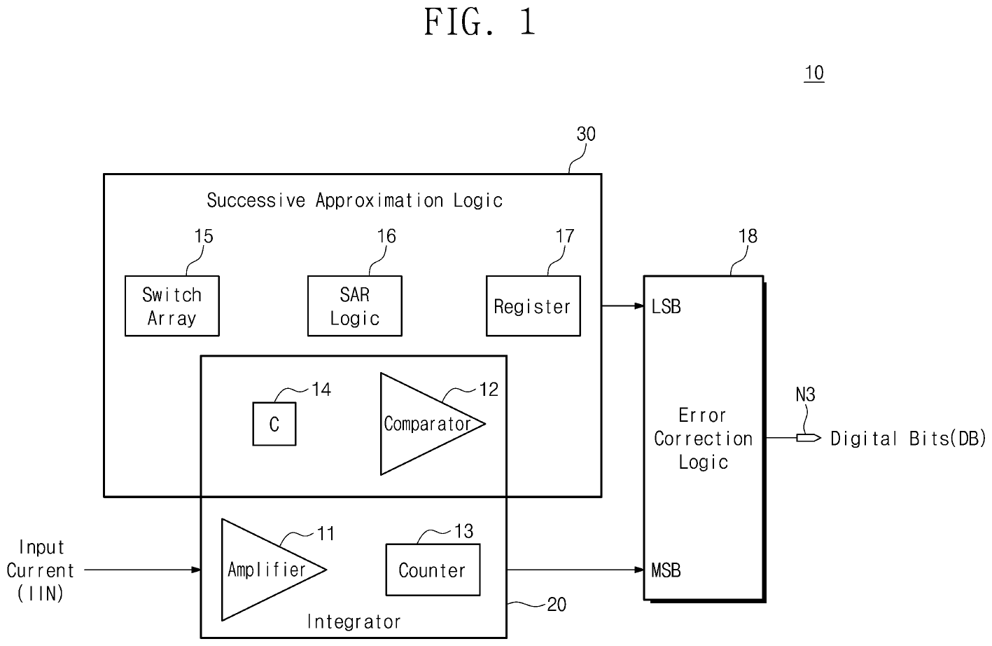

FIG. 1 is a block diagram illustrating an analog-to-digital converter 10 according to an embodiment of the inventive concept. Referring to FIG. 1, the analog-to-digital converter 10 may include an integrator 20, successive approximation unit 30, and error correction logic 18.

The analog-to-digital converter 10 may receive an input current IIN and convert the input current IIN into digital bits DB. The analog-to-digital converter 10 may generate a part of the digital bits DB, for example, upper bits including the most significant bit MSB, by using the integrator 20. Also, the analog-to-digital converter 10 may generate a part of the rest of the digital bits DB, for example, lower bits including the least significant bit LSB, by using the successive approximation unit 30.

The error correction logic 18 may correct an error (errors) of bits output from the integrator 20 and the successive approximation unit 30, and output a result as the digital bits DB. That is, the analog-to-digital converter 10 may use a combination of two different analog-to-digital converting algorithms.

The integrator 20 may include an amplifier 11, a comparator 12, a counter 13, and capacitors (C) 14. The amplifier 11 may integrate the input current IIN by using the capacitors 14. The comparator 12 may compare an output of the amplifier 11 with a specific voltage (e.g., a second reference voltage), and selectively output a pulse signal, based on a comparison result. The counter 13 may count pulse signals received from the comparator 12 and output the upper bits including the most significant bit MSB.

The successive approximation unit 30 may include the comparator 12, the capacitors 14, a switch array 15, successive approximation register (SAR) logic 16, and a register 17. The switch array 15 may be connected to the capacitors 14. The SAR logic 16 may adjust the capacitors 14 through the switch array 15 such that a successive approximation is performed.

The comparator 12 may compare a voltage of the capacitors 14 with a specific voltage (e.g., a common voltage VC) and selectively output a pulse signal, based on a comparison result. The register 17 may store outputs of the comparator 12 as the lower bits including the least significant bit (LSB).

In exemplary embodiment, in a first mode, the integrator 20 may be activated and the successive approximation unit 30 may be deactivated. In the first mode, the integrator 20 may generate the upper bits including the most significant bit MSB, using the input current IIN, and generate an integration result. In a second mode, the integrator 20 may be deactivated and the successive approximation unit 30 may be activated. In the second mode, the successive approximation unit 30 may generate the lower bits including the least significant bit (LSB), using the integration result.

The integrator 20 and the successive approximation unit 30 may include the capacitors 14 and the comparator 12 as common components. The analog-to-digital converter 10 may share and use the capacitors 14 and the comparator 12 in the integrator 20 and the successive approximation unit 30. Thus, a size and cost of the analog-to-digital converter 10 may be decreased.

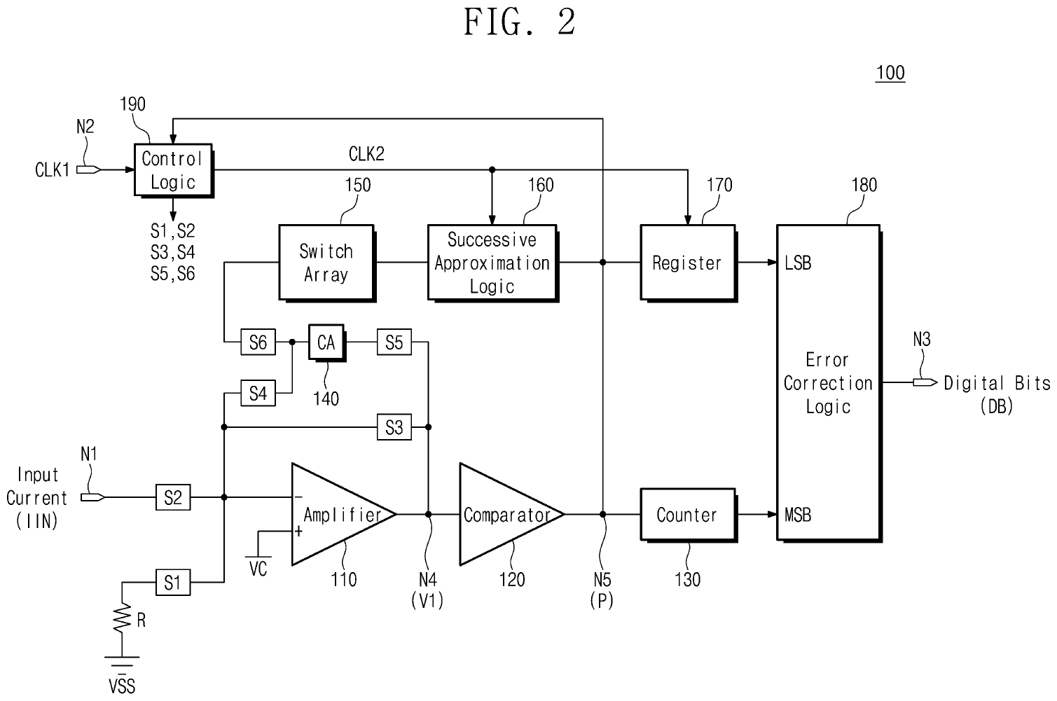

FIG. 2 is a diagram illustrating in more detail an analog-to-digital converter 100 according to an embodiment of the inventive concept. Referring to FIGS. 1 and 2, the analog-to-digital converter 100 may include an amplifier 110, a comparator 120, a counter 130, a capacitor array (CA) 140, a switch array 150, and SAR logic 160, a register 170, error correction logic 180, control logic 190, first to fifth nodes N1 to N5, and first to sixth switches S1 to S6.

The amplifier 110, the comparator 120, the counter 130, the capacitor array (CA) 140, the switch array 150, the SAR logic 160, the register 170, and error correction logic 180 may correspond to the amplifier 11, the comparator 12, the counter 13, the capacitors 14, the switch array 15, the SAR logic 160, the register 17, and the error correction logic 18 described in FIG. 1, respectively.

A negative input (−) of the amplifier 110 may be connected to the first switch S1, the second switch S2, the third switch S3, and the fourth switch S4. The common voltage VC may be supplied to a positive input (+) of the amplifier 110. For example, the common voltage VC may have a level between a power supply voltage VDD and a ground voltage VSS, for example, an intermediate level.

The output of the amplifier 110 may be connected to the fourth node N4. A voltage of the fourth node N4 may be, for example, a first voltage V1. The amplifier 110 may amplify a difference between the common voltage VC of the positive input (+) and a voltage of the negative input (−), and output an amplification result as the first voltage V1.

The comparator 120 may receive the first voltage V1 of the fourth node N4 as an input. The comparator 120 may compare the first voltage V1 with the specific voltage, for example, the common voltage VC. The output of the comparator 120 may be the fifth node N5. The comparator 120 may output a pulse signal P that transitions to a positive level (e.g., the power supply voltage VDD) and then transitions to the ground voltage VSS, when the first voltage V1 is greater than the common voltage VC. The comparator 120 may maintain the ground voltage VSS when the first voltage V1 is less than or equal to the common voltage VC.

The counter 130 may be activated in the first mode to perform counting, and may be deactivated in the second mode to not perform counting. In the first mode, the counter 130 may count the number of pulse signals P. In the second mode, the counter 130 may maintain a count value. The count value of the counter 130 may be transferred to the error correction logic 180, as upper bits including the most significant bit (MSB).

The capacitor array 140 may include a plurality of capacitors connected in parallel between one end and the other end. The one end of the capacitor array 140 may be connected to the fourth switch S4 and the sixth switch S6. The other end of the capacitor array 140 may be connected to the fifth switch S5.

The switch array 150 may include a plurality of switches connected to the plurality of capacitors of the capacitor array 140, respectively. The switch array 150 is connected between the sixth switch S6 and the SAR logic 160.

The SAR logic 160 may be deactivated in the first mode and activated in the second mode. The SAR logic 160 is connected between the switch array 150 and the fifth node N5. The SAR logic 160 may receive a second clock signal CLK2 from the control logic 190. The SAR logic 160 may control the switches of the switch array 150, based on the second clock signal CLK2 and a voltage level of the fifth node N5. The SAR logic 160 may control the switch array 150 such that the successive approximation is performed.

The register 170 may be deactivated in the first mode and activated in the second mode. The register 170 may receive the second clock signal CLK2 from the control logic 190. The register 170 may store the voltage level of the fifth node N5 in synchronization with the second clock signal CLK2. The register 170 may transfer the stored values to the error correction logic 180 as the lower bits including the least significant bit (LSB).

The error correction logic 180 may receive the upper bits including the most significant bit (MSB) from the counter 130 and the lower bits including the least significant bit (LSB) from the register 170. The error correction logic 180 may add the upper bits and the lower bits, perform error correction, and output the digital bits DB to the third node N3.

The third node N3 may be an output node. For example, the error correction logic 180 may perform an error correction by weighting the upper bits or adding the bits after overlapping by one bit, often used in pipelined analog-to-digital conversions.

The control logic 190 may receive a first clock signal CLK1 from an external device through the second node N2. The control logic 190 may control the first to sixth switches S1 to S6 in response to the first clock signal CLK1. The control logic 190 may control activation or deactivation of each of components in the first mode and the second mode. The control logic 190 may also control a timing at which the error correction logic 180 receives the upper bits from the counter 130 and the lower bits from the register 170. The control logic 190 may control the timing at which the error correction logic 180 outputs the digital bits DB.

The control logic 190 may generate the second clock signal CLK2 from the first clock signal CLK1. A frequency of the second clock signal CLK2 may be equal to or greater than a frequency of the first clock signal CLK1. For example, the frequency of the second clock signal CLK2 may be an integer multiple of the frequency of the first clock signal CLK1.

The first switch S1 is connected to the negative input (−) of the amplifier 110. The first switch S1 may be connected to the ground node to which the ground voltage VSS is supplied through a resistor R. The second switch S2 is connected between the negative input (−) of the amplifier 110 and the first node N1. The first node N1 may be the input node to which the input current IIN is input.

The third switch S3 is connected between the negative input (−) of the amplifier 110 and the fourth node N4 that is the output of the amplifier 110. The fourth switch S4 is connected between the negative input (−) of the amplifier 110 and one end of the capacitor array 140. The fifth switch S5 is connected between the fourth node N4 and the other end of the capacitor array 140. The sixth switch S6 is connected between the switch array 150 and one end of the capacitor array 140.

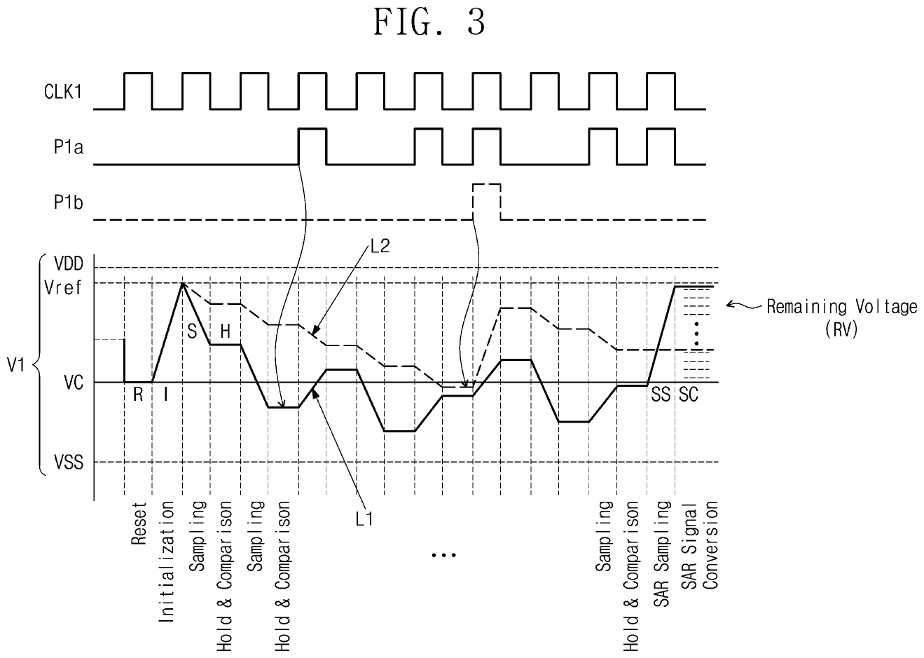

FIG. 3 is a diagram illustrating an example in which the analog-to-digital converter 100 according to the embodiment of the inventive concept performs the conversion. In FIG. 3, the horizontal axis indicates a time and the vertical axis shows voltage levels of the various signals. For example, in FIG. 3, the first clock signal CLK1, a first pulse signal P1a of the first mode as part of the pulse signal P, and a second pulse signal P1b of the second mode as part of the rest of the pulse signal P, and the first voltage V1 swinging between the ground voltage VSS and the power supply voltage VDD are illustrated.

A change in the first voltage V1 is illustrated through a first line L1 and a second line L2. The first line L1 illustrates a change in the first voltage V1 when the input current IIN is relatively large. The second line L2 illustrates a change in the first voltage V1 when the input current IIN is relatively small. First, an operation of the analog-to-digital converter 100 will be described with reference to the first line L1.

Referring to FIGS. 2 and 3, in synchronization with a rising edge of the first clock signal CLK1, a reset interval R of the first mode of the analog-to-digital converter 100 may be performed first. In the reset interval R of the first mode, the first voltage V1, that is, the output voltage of the amplifier 110 may be reset to the common voltage VC.

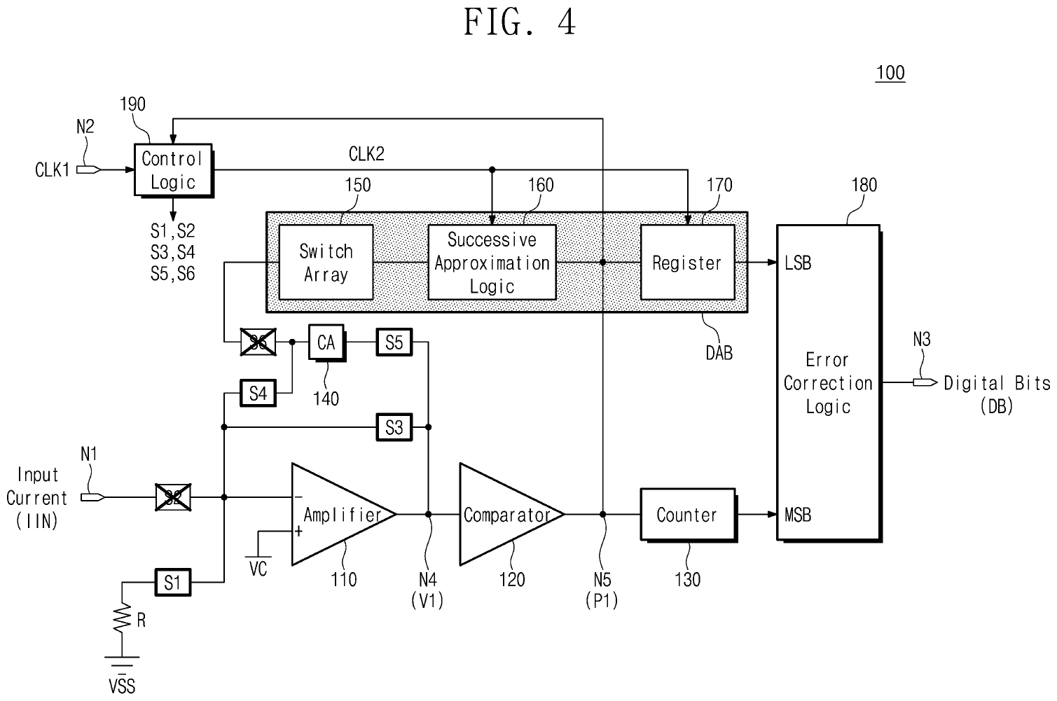

FIG. 4 is a diagram illustrating an example in which the analog-to-digital converter 100 operates in the reset interval R of the first mode. In FIG. 4 and below, the deactivated components are indicated by boxes filled with dots. In FIG. 4, the switches that are turned on are represented by a square of thick lines, and the switches that are turned off are represented by a mark X of thick lines. Referring to FIGS. 3 and 4, the control logic 190 may turn on the first switch S1, the third switch S3, the fourth switch S4, and the fifth switch S5, and turn off the second switch S2 and the sixth switch S6.

Since the common voltage VC is supplied to the positive input (+) of the amplifier 110, and the negative input (−) and the output of the amplifier 110 are shorted through the third switch S3, both the voltage of the negative input (−) of the amplifier 110 and the first voltage V1 that is the output of the amplifier 110 become the common voltage VC. Since the common voltage VC is applied to both ends of the capacitor array 140, the plurality of capacitors of the capacitor array 140 may be reset to not store charges.

In an embodiment, the reset interval R may reset the charges remaining in the capacitor array 140 through the successive approximation of the second mode. The reset interval R may be included at an end of the second mode instead of being included at a start of the first mode. In an embodiment, the first switch S1 may be turned on or turned off in the reset interval R.

For example, in FIG. 4, the first switch S1 is shown to be turned on to prevent a switching noise from occurring in an initialization interval I subsequent to the reset interval R. However, when a drawback of power consumption in which current flows through the resistor (R) to the ground node, is greater than the drawback of the switching noise, the first switch S1 may be turned off in the reset interval R.

Similar to the first switch S1, in the reset interval R, the second switch S2 may also be turned on or turned off. Since the second switch S2 does not cause the switching noise in the initialization interval I subsequent to the reset interval R, the second switch S2 is turned off to prevent unnecessary power consumption from being caused by inflow of the input current IIN.

Referring back to FIG. 3, in synchronization with a falling edge of the first clock signal CLK1, the initialization interval I of the first mode may be performed after the reset interval R of the first mode. In the initialization interval I of the first mode, the first voltage V1 may start to rise. The first voltage V1 may rise from the common voltage VC to a reference voltage Vref.

The reference voltage Vref may be a positive voltage less than the power supply voltage VDD and greater than the common voltage VC. For example, the reference voltage Vref may have a level in a range of 70% to 90% of the power supply voltage VDD.

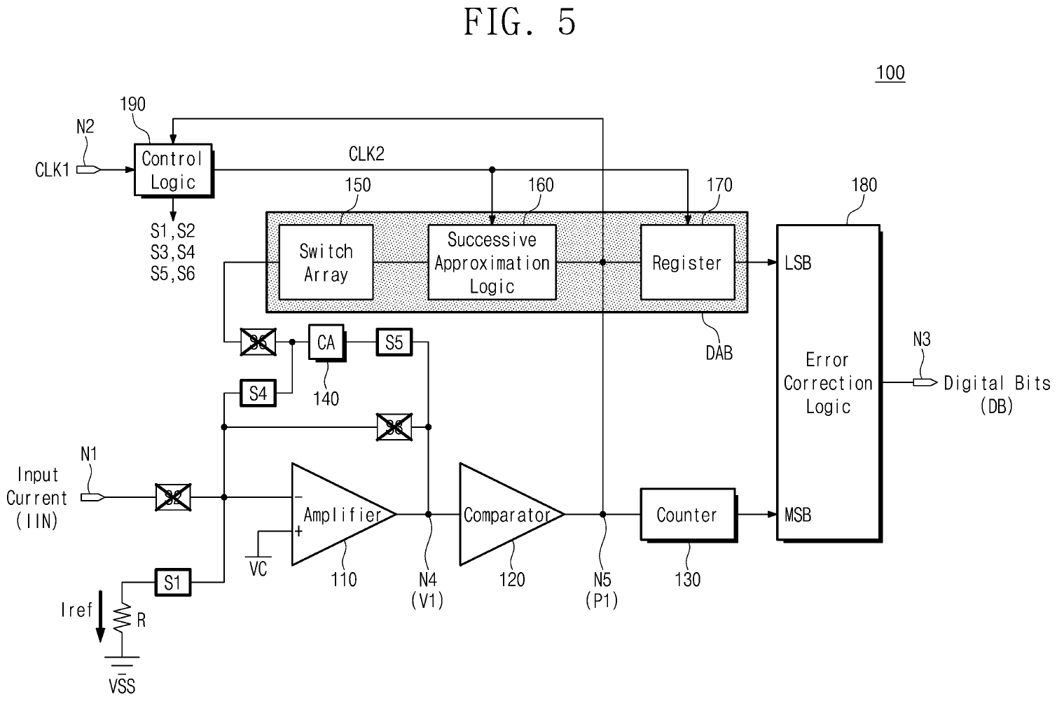

FIG. 5 is a diagram illustrating an example in which the analog-to-digital converter 100 operates in the initialization interval I of the first mode. Referring to FIGS. 3 and 5, the control logic 190 may turn on the first switch S1, the fourth switch S4, and the fifth switch S5, and turn off the second switch S2, the third switch S3, and the sixth switch S6.

The voltage at the positive input (+) of the amplifier 110 is the common voltage (VC), and the negative input (−) is connected to the ground node through a resistor (R). Accordingly, the reference current Iref may flow from the negative input (−) of the amplifier 110 to the ground node. An amount of the reference current Iref may correspond to a value obtained by dividing the common voltage VC by the resistance value of the resistor R.

The fourth node N4 that is the output of the amplifier 110, is connected to the negative input (−) through the capacitor array CA. Thus, the voltage at the negative input (−) of the amplifier 110 maintains the common voltage VC. Since the reference current Iref flows from the fourth node N4 through the capacitor array 140 and the resistor R, the first voltage V1, which is an output voltage of the amplifier 110, may increase. For example, the amplifier 110 may function as an integrator that integrates the reference current Iref, using the capacitor array 140.

A level of the reference voltage Vref may be determined by the amount of current of the reference current Iref and a capacitance of the capacitor array 140. The resistance value of the resistor R or the capacitance of the capacitor array 140 may be adjusted such that the level of the reference voltage Vref becomes a target value.

Referring to FIG. 3 again, in synchronization with the rising edge of the first clock signal CLK1, a sampling interval S of the first mode may be performed subsequent to the initialization interval I of the first mode. In the sampling interval S, the first voltage V1 may decrease as much as the input current IIN.

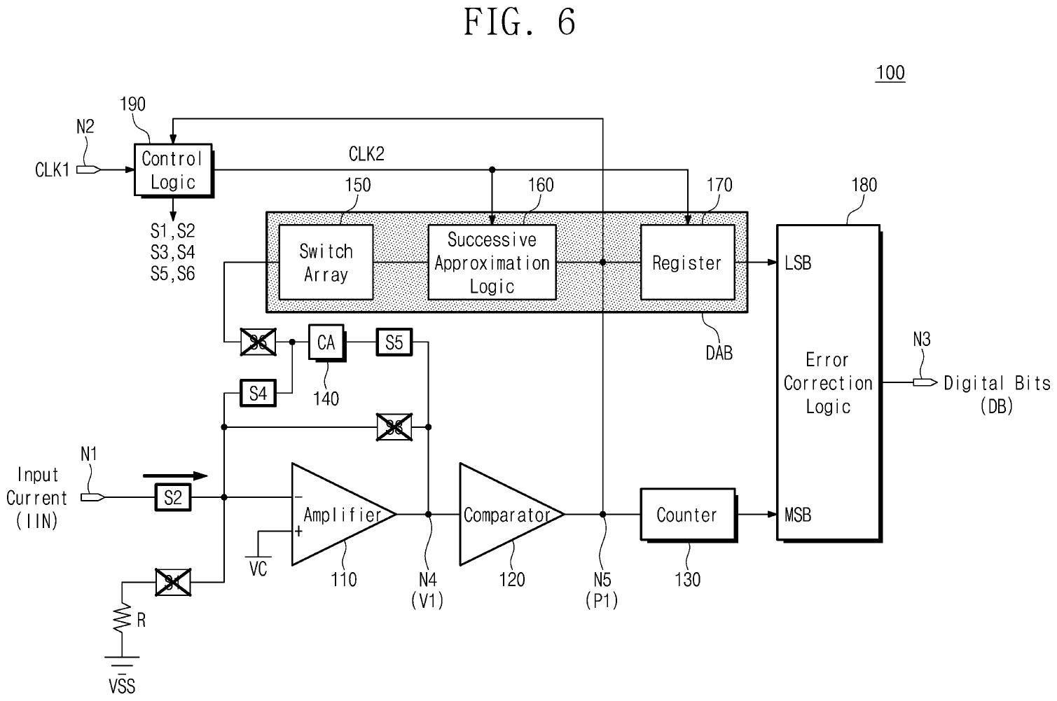

FIG. 6 is a diagram illustrating an example in which the analog-to-digital converter 100 operates in the sampling interval S of the first mode. Referring to FIGS. 3 and 6, the control logic 190 may turn on the second switch S2, the fourth switch S4, and the fifth switch S5, and turn off the first switch S1, the third switch S3, and the sixth switch S6.

Since the second switch S2 is turned on, the input current IIN is transferred to the negative input (−) of the amplifier 110. The amplifier 110 may function as an integrator that integrates the input current IIN, using the capacitor array 140. Since the direction of the input current IIN is a direction input to the amplifier 110, the first voltage V1 may decrease as much as the amount of current of the input current IIN and the capacitance of the capacitor array 140.

Referring to FIG. 3 again, in synchronization with the falling edge of the first clock signal CLK1, a hold and comparison interval H of the first mode may be performed subsequent to the sampling interval S of the first mode. In the hold and comparison interval H, the level of the first voltage V1 may be added to the value of the upper bits including the most significant bit MSB.

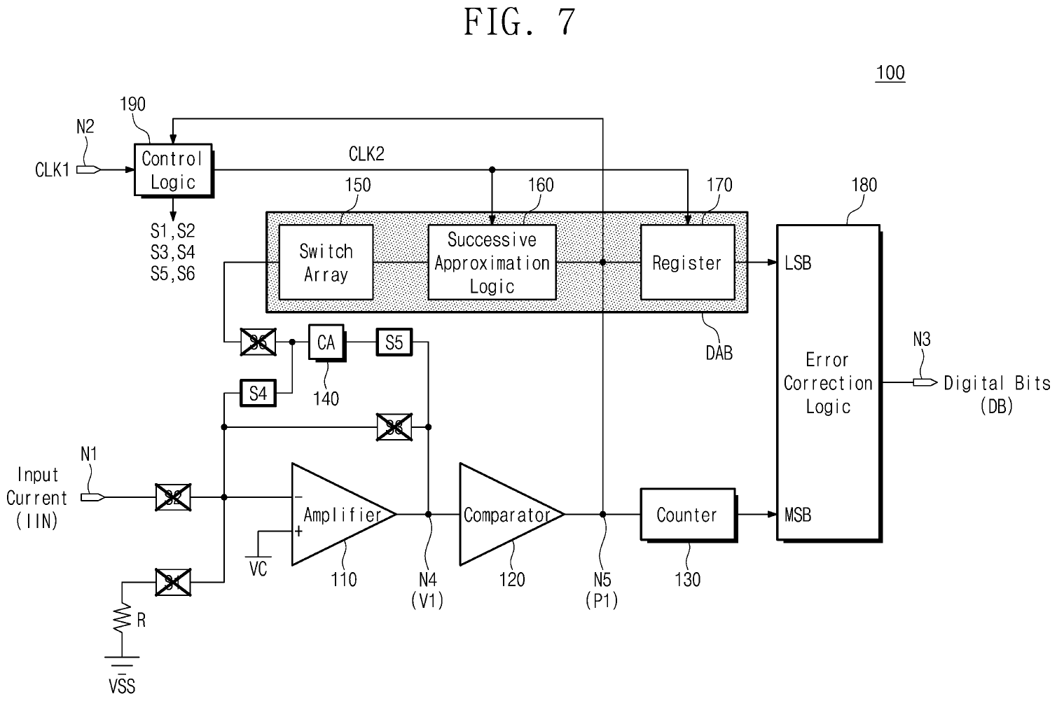

FIG. 7 is a diagram illustrating an example in which the analog-to-digital converter 100 operates in the hold and comparison interval H of the first mode. Referring to FIGS. 3 and 7, in the hold and comparison interval H of the first mode, the control logic 190 may turn on the fourth switch S4 and the fifth switch S5, and turn off the first switch S1, the second switch S2, the third switch S3, and the sixth switch S6.

Since no current is input to the amplifier 110, the first voltage V1 that is the output of the amplifier 110 may maintain a level. The comparator 120 may compare the first voltage V1 with the common voltage VC. When the first voltage V1 is greater than the common voltage VC, the comparator 120 may output the first pulse signal P1 that transitions to the high level of the power supply voltage VDD and then transitions to the ground voltage. When the first voltage V1 is equal to or less than the common voltage VC, the comparator 120 may not output the first pulse signal P1.

The counter 130 may increase the count value in response to the first pulse signal P1. The count value of the counter 130 may be a value represented by upper bits including the most significant bit (MSB).

Referring to FIG. 3 again, the sampling interval S and the hold and comparison interval H may be repeated. When the first pulse signal P1 does not occur, that is, when the first voltage V1 is greater than the common voltage VC, as described with reference to FIG. 6, the analog-to-digital converter 100 may perform the sampling interval S of the first example in which the first voltage V1 is decreased by using the input current IIN.

When the first pulse signal P1 occurs, that is, when the first voltage V1 is equal to or less than the common voltage VC, the analog-to-digital converter 100 may perform the sampling interval S of the second example in which the first voltage V1 is increased by using the input current IIN.

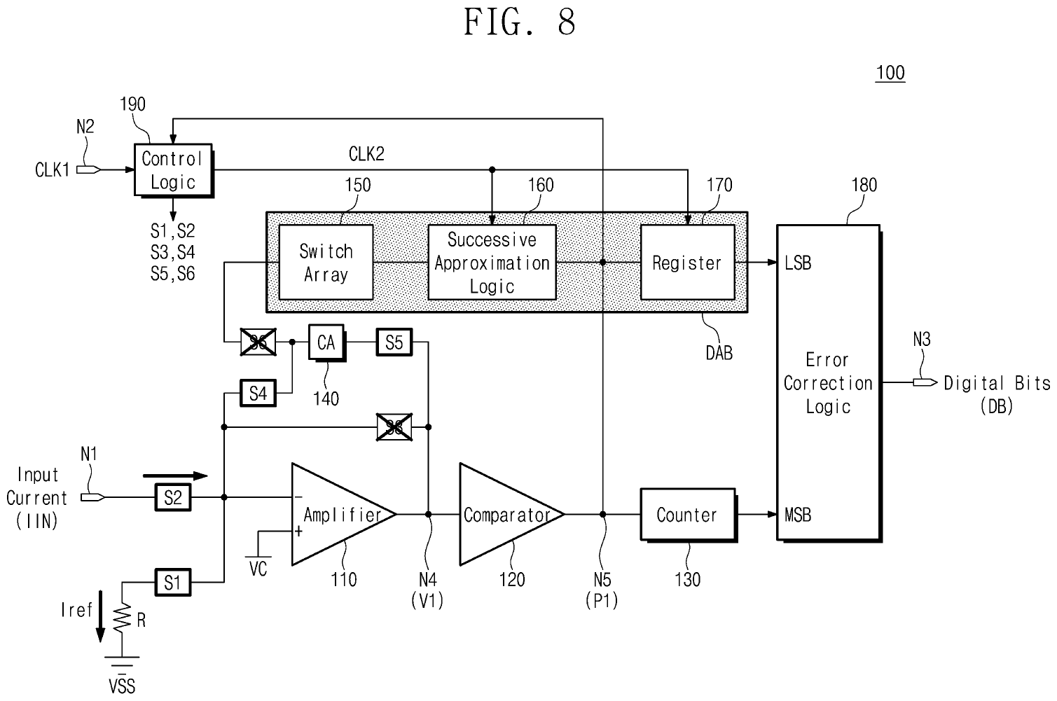

FIG. 8 is a diagram illustrating an example in which the analog-to-digital converter 100 operates in the sampling interval S of the second mode. Referring to FIGS. 3 and 8, the control logic 190 may turn on the first switch S1, the second switch S2, the fourth switch S4, and the fifth switch S5, and turn off the third switch S3 and the sixth switch S6.

The input current IIN may be input from the first node N1 to the negative input (−) of the amplifier 110 and the reference current Iref may be output from the negative input (−) of the amplifier 110 to the ground node through the resistor R. The amount of the reference current Iref may be set greater than an amount of the input current IIN. The first voltage V1 may increase by a value obtained by subtracting the amount of the input current IIN from the amount of the reference current Iref and by the capacitance of the capacitor array 140.

When the analog-to-digital converter 100 generates n bits (n is a positive integer) using the first mode, the first mode may be performed through 2\hat{ }n sampling intervals S and hold and comparison intervals H. When the sampling interval S and the hold and comparison interval H are performed at the rising edge and the falling edge of the first clock signal CLK1, respectively, the first mode may be performed through 2\hat{ }n clock cycles.

As the amount of the input current IIN increases, the number of times that the first pulse signal P1 is generated may increase. During 2\hat{ }n clock cycles, the first pulse signal P1 may occur up to 2\hat{ }n times. That is, the count value of the counter 130 may correspond to a value represented by n bits. That is, n bits may be obtained from the count value of the counter 130.

Referring again to the second line L2 of FIG. 3, the number of the second pulse signals P2 that represents an example in which the amount of the input current IIN is relatively small, is less than the number of the first pulse signals P1. As the count value of the counter 130 increases, the value of the upper bits including the most significant bit MSB increases, and the amount of the input current IIN may be relatively large. Likewise, as the count value of the counter 130 decreases, the value of the upper bits including the most significant bit MSB may be decreased, and the amount of the input current IIN may be relatively small.

When the first mode is completed, a SAR sampling interval SS of the second mode may be performed in synchronization with the rising edge of the first clock signal CLK1. In the SAR sampling interval SS, when the first voltage V1 is greater than the common voltage VC, the control logic 190 may maintain the first voltage V1 as described with reference to FIG. 7.

In the SAR sampling interval SS, when the first voltage V1 is equal to or lower than the common voltage VC, the control logic 190 may increase the first voltage V1 by the difference between the reference voltage Vref and the common voltage VC, using the reference current Iref as described with reference to FIG. 5.

A SAR signal conversion interval SC of the second mode may be performed in synchronization with the falling edge of the first clock signal CLK1. In the SAR signal conversion interval SC, the analog-to-digital converter 100 may generate the lower bits by performing the successive approximation within a range of the reference voltage Vref and the common voltage VC.

A remaining voltage RV of the capacitor array 140 may be a result of the integration of the analog-to-digital converter 100. The remaining voltage RV is a result of performing integration using the input current IIN, and represents a result after extracting the upper bits from the input current IIN. That is, the lower bits may be extracted from the remaining voltage RV.

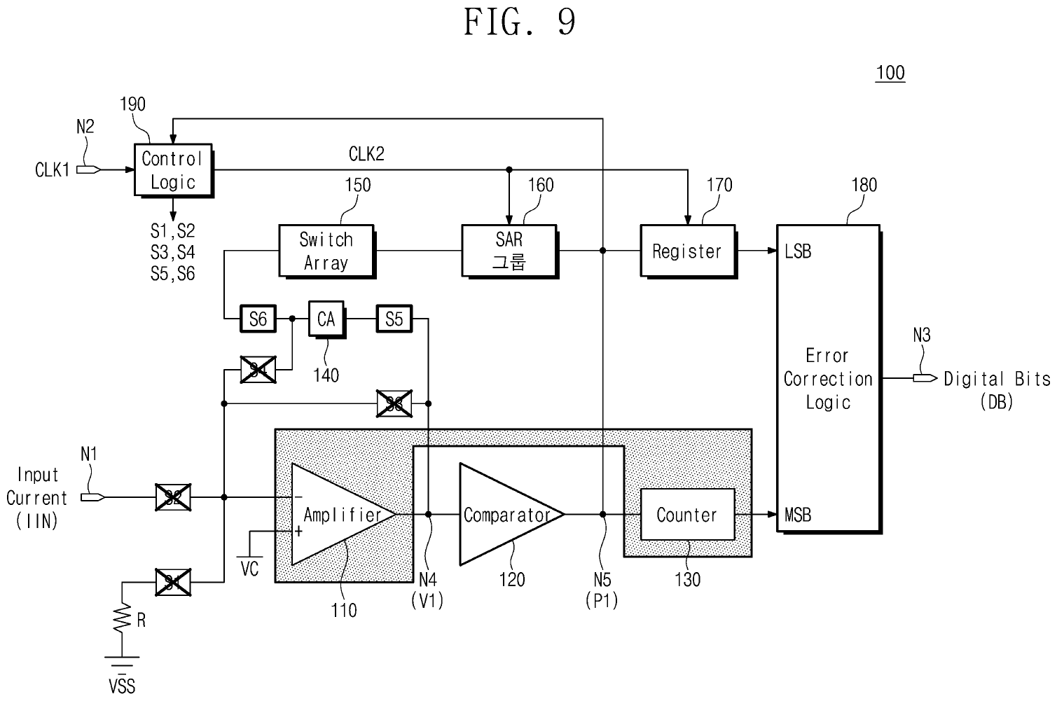

FIG. 9 is a diagram illustrating an example in which the analog-to-digital converter 100 operates in the signal conversion interval SC of the second mode. Referring to FIGS. 3 and 9, the control logic 190 may turn on the fifth switch S5 and the sixth switch S6, and turn off the first switch S1, the second switch S2, the third switch S3, and the fourth switch S4.

The control logic 190 may activate the SAR logic 160 and the register 170 to perform the successive approximation in response to the second clock signal CLK2. The SAR logic 160 may control the switch array 150 to adjust a voltage transferred from the capacitor array 140 to the comparator 120. The comparator 120 may compare the voltage transferred from the capacitor array 140 with the common voltage VC.

The comparator 120 may output a comparison result as each bit of the lower bits. The SAR logic 160 may control the switch array 150 to perform the successive approximation, in response to the output of the comparator 120. The register 170 may store values sequentially output from the comparator 120 as each bit of the lower bits.

For example, when the analog-to-digital converter 100 determines ‘m’ lower bits through the successive approximation, ‘m’ successive approximation may be performed. The control logic 190 may adjust the frequency of the second clock signal CLK2 to 2m times the first clock signal CLK1. In this case, the successive approximation may be completed during a clock cycle of half of the first clock signal CLK1.

That is, the analog-to-digital converter 100 may generate n+m digital bits DB through one clock cycle for the reset interval R and the initialization interval I, 2\hat{ }n clock cycles for the sampling interval S and the hold and comparison interval H, and one clock cycle (clock cycle of the first clock signal CLK1) for the successive approximation. Thus, the number of clock cycles may be decreased than when performing the conversion using only the integration.

In the above-described embodiments, in the initialization interval I, the first voltage V1 is initialized to the reference voltage Vref higher than the common voltage VC. Accordingly, the comparator 120 may generate the upper bits by comparing the common voltage VC with the reference voltage Vref.

When the initialization interval I is omitted, the first voltage V1 may be sampled from the common voltage VC. In this case, to generate the upper bits, the comparator 120 must compare another voltage (e.g., an additional reference voltage) lower than the common voltage VC with the first voltage V1. In other words, additional components are needed to generate the additional reference voltage.

The analog-to-digital converter 100 according to an embodiment of the inventive concept initializes the first voltage V1 to the reference voltage Vref through the initialization interval I. Thus, the comparator 120 may compare the common voltage VC already in use with the first voltage V1, thus preventing the addition of components.

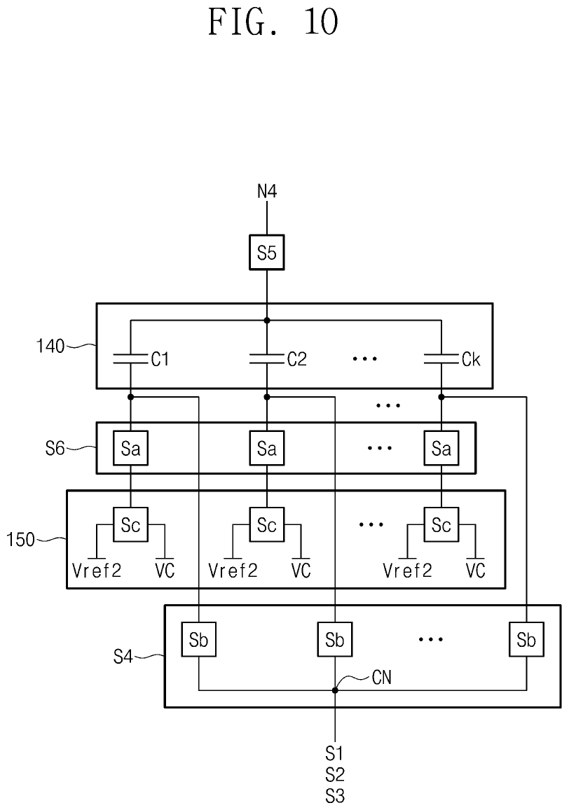

FIG. 10 is a diagram illustrating an example of a capacitor array 140 and switches associated with it according to an embodiment of the inventive concept. Referring to FIGS. 2 and 10, the capacitor array 140 may include first to ‘k’th capacitors C1 to Ck (k is a positive integer) connected in parallel to one another. The first to ‘k’th capacitors C1 to Ck may have the same capacitances or different capacitances.

For example, when the first to ‘k’th capacitors C1 to Ck have the same capacitances, a value of k may be 2\hat{ }m. The ‘m’ may be the number of lower bits that the analog-to-digital converter 100 intends to generate through the successive approximation. Alternatively, when a dummy capacitor is used, the value of k may be 2m+1. That is, the number of capacitors may be significantly decreased compared to when generating n+m bits only by using the successive approximation.

The sixth switch S6 may include first sub-switches Sa connected to the first to ‘k’ th capacitors C1 to Ck, respectively. The fourth switch S4 may include second sub-switches Sb connected to the first to k th capacitors C1 to Ck, respectively. The switch array 150 may include third sub-switches Sc connected to the first sub-switches Sa, respectively.

The first to k th capacitors C1 to Ck may be respectively connected to the third sub switches Sc through the first sub switches Sa or commonly connected to the common node CN through the second sub switch Sb under a control of the control logic 190. The common node CN may be connected to the first switch S1, the second switch S2, and the third switch S3.

In the first mode, the first to k th capacitors C1 to Ck are connected to the common node CN through the second sub switches Sb. Therefore, the first to k th capacitors C1 to Ck may be regarded as one capacitor connected between the fifth switch S5 and the common node CN.

In the second mode, the first to k th capacitors C1 to Ck are respectively connected to the third sub switches Sc through the first sub switches Sa. Each of the third sub-switches Sc may selectively apply one of a second reference voltage Vref2 and the common voltage VC to a corresponding one of the first to k th capacitors C1 to Ck. The second reference voltage Vref2 may have a level in the range of the common voltage VC to the reference voltage Vref.

After the first mode is completed, the voltage charged in the first to k th capacitors C1 to Ck may correspond to the sampled input voltage of the successive approximation. Therefore, unlike circuits of a conventional successive approximation, the third sub-switches Sc may not include switching nodes for sampling the input voltage to the first to k th capacitors C1 to Ck.

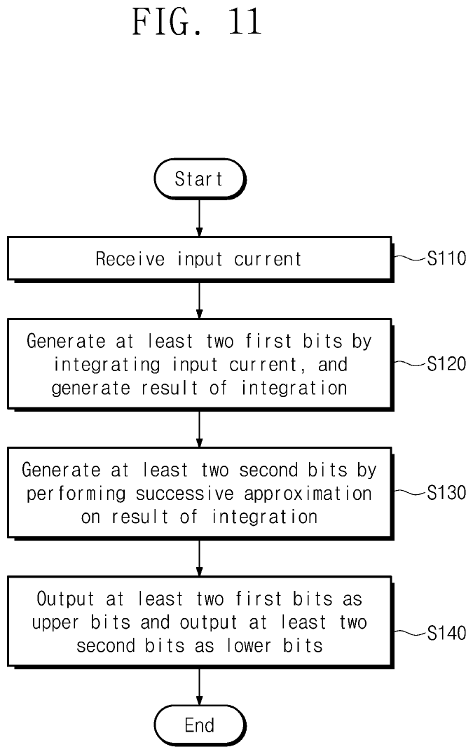

FIG. 11 is a flowchart describing an operating method of the analog-to-digital converter 100 according to an embodiment of the inventive concept. Referring to FIGS. 2 and 11, in step S110, the analog-to-digital converter 100 may receive the input current IIN. In step S120, the analog-to-digital converter 100 may generate at least two first bits by integrating the input current IIN, and generate the result of the integration.

The analog-to-digital converter 100 may integrate the input current IIN by using the amplifier 110 and the capacitor array 140. The analog-to-digital converter 100 may generate at least two first bits, using the comparator 120 and the counter 130. The analog-to-digital converter 100 may leave the remaining voltage RV in the capacitor array 140 as a result of the integration.

In operation S130, the analog-to-digital converter 100 may generate at least two second bits by performing the successive approximation on the result of the integration. The analog-to-digital converter 100 may perform the successive approximation using the capacitor array 140, the comparator 120, the switch array 150, the SAR logic 160, and the resister 170, and generate the at least two second bits.

In operation S140, the analog-to-digital converter 100 may output the at least two first bits as the upper bits and the at least two second bits as the lower bits. The analog-to-digital converter 100 may perform the error correction, using the error correction logic 180. In operations S120 and S130, the analog-to-digital converter 100 may share and use the capacitor array 140 and the comparator 120.

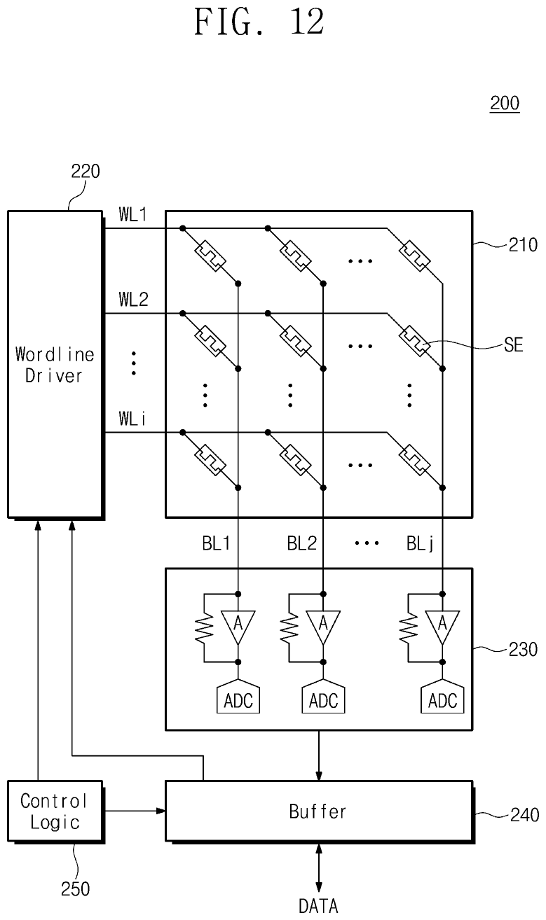

FIG. 12 is a block diagram illustrating a neuromorphic processor 200 according to an embodiment of the inventive concept. Referring to FIG. 12, the neuromorphic processor 200 may include a synapse element array 210, a word line driver 220, a bit line bias and detection block 230, a buffer 240, and control logic 250.

The synapse element array 210 may include a plurality of synapse elements SE. The synapse elements SE may be arranged in rows and columns. The rows of the synapse elements may be connected to first to ‘i’ th word lines WL1 to WLi (i is a positive integer). The columns of the synapse elements SE may be connected to first to j th bit lines BL1 to BLj, respectively.

Each of the synapse elements SE may have a resistance value corresponding to the synapse value (or weight). For example, the synapse elements SE may include a memristor or a variable resistance element. The variable resistance element may include a nonvolatile memory such as a magnetic memory, a ferroelectric memory, a phase change memory, a resistive memory, etc.

The word line driver 220 is connected to the first to i th word lines WL1 to WLi. The word line driver 220 may provide input information to the first to i th word lines WL1 to WLi. For example, the word line driver 220 may simultaneously provide the input information to the first to i th word lines WL1 to WLi.

The bit line bias and detection block 230 is connected to the first to j th bit lines BL1 to BLj. The bit line bias and detection block 230 may select one bit line among the first to j th bit lines BL1 to BLj as a target of a machine learning operation. The synapse elements SE of a selected row may provide output information (e.g., currents) to the bit line of a selected column, based on the input information (e.g., voltages) provided from the word line driver 220 and stored synaptic value (e.g., resistance value).

Depending on the synapse value and the input information, each of the synapse elements SE may flow a large current or a small current. The currents flowing through the synapse elements SE of the selected row may be summed at the bit lines of the selected column. The bit line bias and detection block 230 may obtain results of operations of the synapse elements SE by detecting an amount of current of currents flowing through the first to j th bit lines BL1 to BLj.

The bit line bias and detection block 230 may include one amplifier A for each of the first to j th bit lines BL1 to BLj, a resistor connected between an input and an output of the amplifier A, and an analog-to-digital converter ADC. The analog-to-digital converter ADC may include the analog-to-digital converter 100 described with reference to FIGS. 1 to 11.

A sequence of procedures in which the outputs of the synapse elements SE of the selected column are collected at the corresponding bit line is similar to a mechanism by which one neuron receives information through the synapse elements and provides an output. Thus, columns of synapse elements SE may be considered neurons.

The buffer 240 may exchange data with an external device. The buffer 240 may transfer the input information provided from the external device as data, to the word line driver 220. The buffer 240 may output the output information transferred from the bit line bias and detection block 230 as data to the external device.

The control logic 250 may control components of the neuromorphic processor 200 such that the neuromorphic processor 200 performs designed operations.

In order for the neuromorphic processor 200 to enable image identification, the neuromorphic processor 200 must include at least 512×512 synapse elements SE. Even though the neuromorphic processor 200 is implemented on the basis of a binarized neural network BNN in which a feature and a weight are small, the feature requires 4 bits and the weight requires 1 bit. In this case, the analog-to-digital converter ADC must have a resolution of at least 13 bits.

To implement 13-bit resolution based on the successive approximation, more than 8000 capacitors are needed. To implement 13-bit resolution based on the integrator, more than 8192 clock cycles are required. The analog-to-digital converter ADC according to an embodiment of the inventive concept may be applied to the neuromorphic processor 200 that requires a reduced size and improved operating speed, by performing the analog-to-digital conversion based on the integrator and the successive approximation,

In the above-described embodiments, the components according to the inventive concept have been described using terms such as first, second, third, etc. However, the terms such as first, second, third, etc. are used to distinguish the components from one another, and do not limit the inventive concept. For example, the terms such as first, second, third, etc. do not imply an order meaning or any form of numeric meaning.

In the above-described embodiments, reference has been made to components according to embodiments of the inventive concept, using blocks. The blocks may be implemented as various hardware devices such as integrated circuits (ICs), application specific ICs (ASICs), field programmable gate arrays (FPGAs), complex programmable logic devices (CPLDs), firmware running on the hardware devices, software such as applications, or a combination of the hardware device and software. In addition, the blocks may include circuits composed of semiconductor elements in the ICs or circuits registered with an intellectual property (IP).

According to embodiments of the inventive concept, an analog-to-digital conversion is performed by mixing an integration and a successive approximation. In addition, at least one component is shared and used in the integration and the successive approximation. Thus, there are provided an analog-to-digital converter and an operating method of the analog-to-digital converter having an improved resolution while preventing an increase in size or an increase in conversion time.

The contents described above are specific embodiments for implementing the inventive concept. The inventive concept may include not only the embodiments described above but also embodiments in which a design is simply or easily capable of being changed. In addition, the inventive concept may also include technologies easily changed to be implemented using embodiments. Therefore, the scope of the inventive concept is not limited to the described embodiments but should be defined by the claims and their equivalents.

What is claimed is:

1. An analog-to-digital converter comprising:
a capacitor array including a plurality of capacitors;
an amplifier configured to receive an input current through an input node and integrate the input current, using the capacitor array, in a first mode;
a switch array including a plurality of switches respectively connected to the plurality of capacitors;
successive approximation logic configured to perform a successive approximation by selectively connecting each of the plurality of capacitors to one of a common voltage and a reference voltage through the plurality of switches, in a second mode;
a comparator configured to compare the common voltage with an output of the amplifier and output a pulse signal based on the comparison result;
a counter configured to count the pulse signal in the first mode;
a register configured to sequentially store values of the pulse signal, in the second mode; and
error correction logic configured to store an output of the counter as upper bits and an output of the register as lower bits and perform error correction to generate digital bits.

2. The analog-to-digital converter of claim 1, further comprising:
a first switch and a resistor connected in series between a first input of the amplifier and a ground node;
a second switch connected between the first input of the amplifier and the input node;
a third switch connected between the output of the amplifier and the first input of the amplifier;
a fourth switch connected between a first terminal of the capacitor array and the first input of the amplifier;
a fifth switch connected between a second terminal of the capacitor array and the output of the amplifier; and
a sixth switch connected between the first terminal of the capacitor array and the switch array.

3. The analog-to-digital converter of claim 2, wherein the first input of the amplifier is a negative input, and the common voltage is input to a second input of the amplifier.

4. The analog-to-digital converter of claim 2, further comprising:
control logic configured to receive a first clock signal, control the first to sixth switches in the first mode and the second mode in response to the first clock signal, generate a second clock signal from the first clock signal, and supply the second clock signal to the switch array, the successive approximation logic, and the register in the second mode.

5. The analog-to-digital converter of claim 2, wherein, in a reset interval of the first mode, the first switch, the third switch, the fourth switch, and the fifth switch are turned on, and the second switch and the sixth switch are turned off.

6. The analog-to-digital converter of claim 2, wherein, in an initialization interval of the first mode, the first switch, the fourth switch, and the fifth switch are turned on, and the second switch, the third switch, and the sixth switch are turned off.

7. The analog-to-digital converter of claim 2, wherein, in a sampling interval of the first mode, when an output of the comparator is a low level, the second switch, the fourth switch and the fifth switch are turned on, and the first switch, the third switch and the sixth switch are turned off.

8. The analog-to-digital converter of claim 2, wherein, in a sampling interval of the first mode, when an output of the comparator is a high level, the first switch, the second switch, the fourth switch, and the fifth switch are turned on, and the third switch, and the sixth switch are turned off.

9. The analog-to-digital converter of claim 2, wherein, in a hold and comparison interval of the first mode, the fourth switch, and the fifth switch are turned on, and the first switch, the second switch, the third switch, and the sixth switch are turned off.

10. The analog-to-digital converter of claim 2, wherein, in the second mode, the fifth switch and the sixth switch are turned on, and the first switch, the second switch, the third switch, and the fourth switch are turned off.

11. The analog-to-digital converter of claim 2,
wherein the sixth switch includes a plurality of first sub-switches respectively connected between the plurality of capacitors of the capacitor array and the plurality of switches,
wherein the fourth switch includes a plurality of second sub-switches connected between the plurality of capacitors and a common node, and
wherein the common node is commonly connected to the first switch, the second switch, and the third switch.

12. The analog-to-digital converter of claim 1, wherein, in a reset interval of the first mode, the output of the amplifier is reset to the common voltage.

13. The analog-to-digital converter of claim 1, wherein, in an initialization interval of the first mode, the output of the amplifier is initialized to a second reference voltage greater than the common voltage.

14. The analog-to-digital converter of claim 1, wherein, in a sampling interval of the first mode, when the output of the amplifier is greater than the common voltage, a voltage level of the output of the amplifier decreases, and when the output of the amplifier is less than the common voltage, the voltage level of the output of the amplifier increases.

15. The analog-to-digital converter of claim 1, wherein, in a hold and comparison interval of the first mode, the comparator outputs the pulse signal when a voltage level of the output of the amplifier is less than the common voltage.

16. The analog-to-digital converter of claim 1, wherein, when entering the second mode from the first mode, when a voltage level of the output of the amplifier is greater than the common voltage, the voltage level is maintained, and
wherein, when the voltage level is less than the common voltage, the voltage level is increased.

17. The analog-to-digital converter of claim 1, wherein, in the second mode, the successive approximation logic performs the successive approximation with respect to a voltage level of the output of the amplifier between a second reference voltage and the common voltage.

18. The analog-to-digital converter of claim 1, wherein the input current is transferred from a plurality of synapse elements of a neuromorphic processor.

19. A method of operating an analog-to-digital converter, the method comprising:
receiving an input current;
generating at least two first bits by integrating the input current, and generating a result of the integration;
generating at least two second bits by performing a successive approximation on the result of the integrating; and
outputting the at least two first bits as upper bits and the at least two second bits as lower bits.

20. The method of claim 19, wherein, in generating the first bits and generating the second bits, capacitors and a comparator are shared and used.
